(19) United States
(12) Patent Application Publication
(10) Pub. No.: US 2005/0078460 A1
(43) Pub. Date: Apr. 14, 2005

(54) Printed circuit board assembly mounting system

(76) Inventors: Owen T. Richard, Fort Collins, CO (US); Ronald P. Dean, Fort Collins, CO (US); Clint E. Conrady, Fort Collins, CO (US); Kristina L. Mann, Fort Collins, CO (US); Jonathan D. Bassett, Fort Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/684,993

(22) Filed: Oct. 14, 2003

(51) Int. Cl. H05K 5/00; H05K 5/04; H05K 5/06

(52) U.S. Cl. 361/753

(57) ABSTRACT

A printed circuit board assembly mounting system comprises a chassis support having at least one keyhole. The keyhole is adapted to receive a mounting post coupled to a printed circuit board assembly. The chassis support further comprises at least one guide adapted to align the mounting post with the keyhole. The mounting post is adapted to slidably engage the keyhole to secure the printed circuit board assembly to the chassis support.

### TECHNICAL FIELD OF THE INVENTION

The present invention relates generally to the field of electronic equipment and, more particularly, to a printed circuit board assembly mounting system.

### BACKGROUND OF THE INVENTION

Printed circuit boards, such as a motherboard or other types of electronic circuit boards, are generally installed within a computer chassis using fasteners, such as screws, installed through industry standard mounting holes formed in the circuit board. The screws may be installed through the industry standard mounting holes into a computer chassis support member or, alternatively, into a removable chassis tray.

Using fasteners to locate and install circuit boards within a computer chassis is generally a time-consuming process. For example, the quantity and size of the fasteners required to install the circuit board results in a difficult and tedious installation procedure, thereby reducing the ability to quickly or easily replace circuit boards. Additionally, providing a chassis tray generally increases the weight of the computer system, thereby also increasing the material and shipping costs of the computer system.

### SUMMARY OF THE INVENTION

In accordance with one embodiment of the present invention, a printed circuit board assembly mounting system comprises a chassis support having at least one keyhole. The keyhole is adapted to receive a mounting post coupled to a printed circuit board. The chassis support further comprises at least one guide adapted to align the mounting post with the keyhole. The mounting post is adapted to slidably engage the keyhole to secure the printed circuit board to the chassis support.

### BRIEF DESCRIPTION OF THE DRAWINGS

For a more complete understanding of the present invention and the advantages thereof, reference is now made to the following descriptions taken in connection with the accompanying drawings in which:

FIG. 1 is a diagram illustrating an exploded view of an embodiment of a printed circuit board assembly mounting system in accordance with the present invention; and

FIG. 2 is a diagram illustrating an enlarged view of a grounding clip of the mounting system of FIG. 1.

### DETAILED DESCRIPTION OF THE DRAWINGS

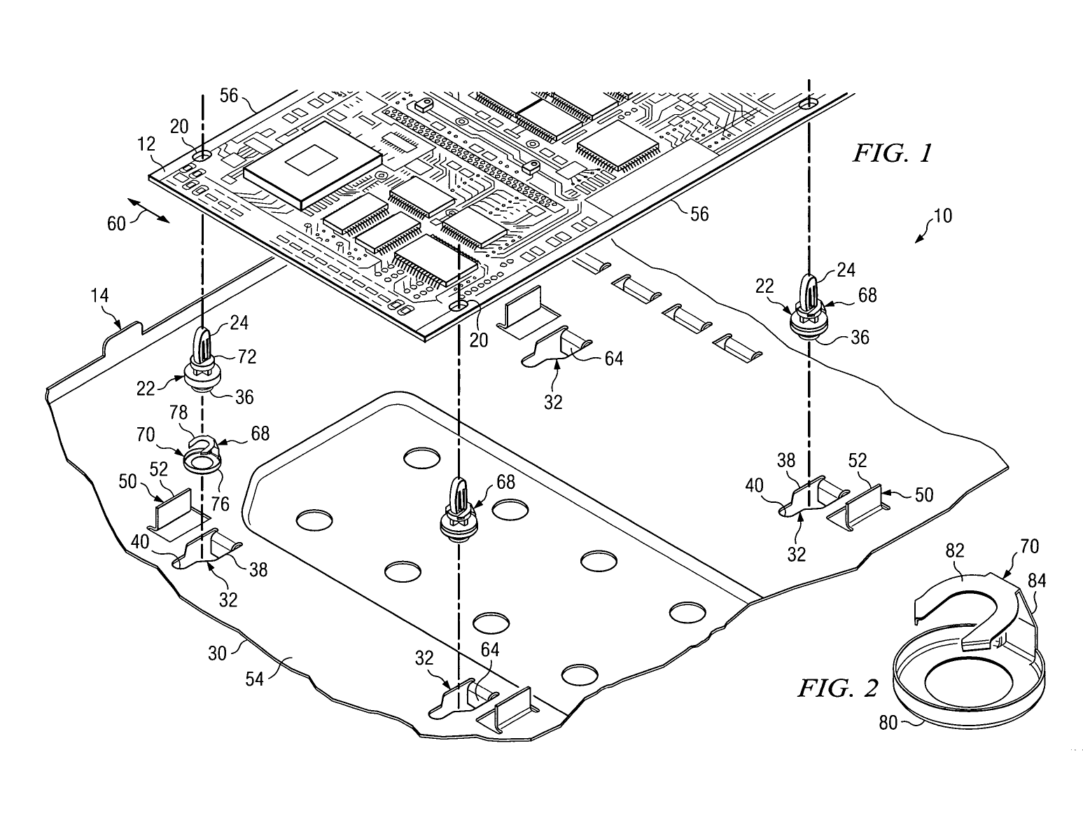

The preferred embodiments of the present invention and the advantages thereof are best understood by referring to FIGS. 1 and 2 of the drawings, like numerals being used for like and corresponding parts of the various drawings.

FIG. 1 is a diagram illustrating an exploded view of an embodiment of a printed circuit board assembly mounting system 10 in accordance with the present invention. Briefly, system 10 provides for easy installation and removal of a printed circuit board assembly 12, such as a motherboard or other type of electronic card, into a computer chassis 14. The computer chassis 14 may comprise a desktop chassis, server chassis, or any other type of computer housing adapted for receiving electronic cards.

As illustrated in FIG. 1, printed circuit board assembly 12 comprises at least one opening 20 for receiving at least one mounting post 22. In some embodiments, mounting post 22 is formed from nonconductive materials, such as plastic, to prevent undesired electrical conductance between printed circuit board assembly 12 and adjacent structure. However, it should be understood that mounting post 22 may also be constructed from conductive materials to enable conductivity between printed circuit board assembly 12 and an adjacent structure. In the embodiment illustrated in FIG. 1, openings 20 are formed having a circular configuration for receiving a corresponding circular-shaped flexible clip portion 24 of mounting post 22 such that, upon insertion of clip portion 24 through openings 20, clip portion 24 releasably secures mounting post 22 to printed circuit board assembly 12. However, it should be understood that printed circuit board assembly 12 may be otherwise configured corresponding to an attachment configuration of mounting post 22. Generally, mounting post 22 comprises a support member adapted to extend from printed circuit board assembly 12 to a portion of chassis 14 to space printed circuit board assembly 12 a predetermined or desired distance from a portion of chassis 14 and provide releasable engagement of printed circuit board assembly 12 to chassis 14 such that printed circuit board assembly 12 may be readily inserted into chassis 14 or removed from chassis 14 with minimal or no assembly or disassembly tools or procedures.

In the embodiment illustrated in FIG. 1, system 10 also comprises a chassis support member 30 adapted to receive an opposite end of mounting post 22. Chassis support 30 may comprise an outer wall or floor of chassis 14 or may comprise a discrete or separate support member installed within chassis 14. As illustrated in FIG. 1, chassis support 30 comprises at least one keyhole 32 corresponding to a location of at least one mounting post 22. In the embodiment illustrated in FIG. 1, mounting post 22 comprises a key portion 36 adapted to cooperate with keyhole 32 to enable releasably securing mounting post 22 to chassis support 30. For example, in operation, key portion 36 may be inserted into an entry/exit portion 38 of keyhole 32 and moved or translated laterally within keyhole 32 into a locking portion 40 of keyhole 32 to releasably secure mounting post 22 to chassis support 30. Thus, in the embodiment illustrated in FIG. 1, slidable engagement of mounting post 22 with keyhole 32 enables releasably securing of printed circuit board assembly 12 to chassis support 30 and provides easy insertion and removal of printed circuit board assembly 12 relative to chassis 14, thereby increasing swapability of printed circuit board assemblies 12 relative to chassis 14. In the embodiment illustrated in FIG. 1, mounting post 22 is configured having a round or circular shape to cooperate with a round or circular shape of locking portion 40. However, it should be understood that mounting post 22 and/or keyhole 21 may be designed having other cooperating shapes or geometries.

In the embodiment illustrated in FIG. 1, chassis support 30 also comprises at least one guide 50 for aligning at least one of the mounting posts 22 with corresponding keyholes 32 during insertion of printed circuit board assembly 12 into chassis 14. For example, in the embodiment illustrated in FIG. 1, each of guides 50 comprises an integrally formed tab 52 of chassis support 30. Each tab 52 extends away from a surface 54 of chassis support 30 facing printed circuit board assembly 12 such that during insertion of printed circuit board assembly 12 into chassis 14, guides 50 direct edges 56 of printed circuit board assembly 12 to a position relative to chassis support 30 to align mounting posts 22 with keyholes 32. Thus, as illustrated in FIG. 1, guides 50 are positioned laterally, as indicated generally at 60, on chassis support 30 corresponding to a lateral dimension of printed circuit board assembly 12. However, it should be understood that guides 50 may be otherwise formed and/or mounted to chassis support 30. For example, in the embodiment illustrated in FIG. 1, guides 50 are formed as integral members of chassis support 30 for ease of manufacture and weight savings; however, it should be understood that guides 50 may also be constructed as separate components that may be attached to chassis support 30.

As illustrated in FIG. 1, guides 50 are disposed on chassis support 30 such that at least one pair of guides 50 are disposed opposite or facing each other to restrict lateral movement of printed circuit board assembly 12 and provide for greater alignment of printed circuit board assembly 12 during insertion of printed circuit board assembly 12 into chassis 14, thereby reducing the likelihood of angling or skewing of printed circuit board assembly 12 during insertion into chassis 14. However, it should be understood that the locations or positions of guides on chassis support 30 may be otherwise varied. Additionally, in the embodiment illustrated in FIG. 1, each keyhole 32 comprises a tab portion 64 extending away from surface 54 to assist disengagement of mounting post 22 from within keyhole 32. For example, during removal of printed circuit board assembly 12 from chassis 14, mounting post 22 is moved from locking portion 40 of keyhole 32 into entry/exit portion 38 of keyhole 32 where mounting post 22 may be withdrawn from within keyhole 32. Tab portion 64 is disposed to a side of keyhole 32 opposite locking portion 40 to prevent inadvertent engagement of key portion 36 of mounting post 22 with chassis support 30 during removal of mounting post 22 from keyhole 32.

In the embodiment illustrated in FIG. 1, system 10 also comprises a grounding element 68 adapted to provide a conductivity path between printed circuit board assembly 12 and chassis support 30. Grounding element 68 may comprise a wire or other type of device for providing a conductivity path between printed circuit board assembly 12 and chassis support 30 for grounding of printed circuit board assembly 12. In the embodiment illustrated in FIG. 1, grounding element 68 comprises a grounding clip 70 adapted to be installed on mounting post 22. For example, each grounding clip 70 is adapted to releasably engage a neck portion 72 of mounting post 22 such that a portion 76 of grounding clip 70 is disposed in contact with a conductive portion of chassis support 30 upon insertion of mounting post 22 into keyhole 32, and a portion 78 of grounding clip 70 is disposed in contact with a conductive portion of printed circuit board assembly 12 upon insertion of mounting post 22 into opening 20.

As further illustrated in FIG. 2, grounding clip 70 comprises a ring portion 80 and a tine portion 82. In operation, ring portion 80 is disposed over key portion 36 of mounting post 22. A connecting arm 84 of grounding clip 70 is constructed having sufficient flexibility to enable tine portion 82 to flex outwardly away from mounting post 22 during installation of ring portion 80 over key portion 36 and return inwardly such that clip portion 24 of mounting post 22 is disposed within tine portion 82. In the embodiment illustrated in FIG. 1, grounding clip 70 is illustrated as being attached to each mounting post 22; however, it should be understood that a greater or fewer quantity of grounding clips 70 may be used to provide the required or desired conductivity paths from printed circuit board assembly 12 to chassis support 30.

1. A printed circuit board assembly mounting system, comprising:
a chassis support having at least one keyhole, the keyhole adapted to receive a mounting post coupled to a printed circuit board assembly, the chassis support further having at least one guide adapted to align the mounting post with the keyhole, the mounting post adapted to slidably engage the keyhole to secure the printed circuit board assembly to the chassis support.

2. The system of claim 1, wherein the guide comprises integrally formed tabs of the mounting support.

3. The system of claim 1, wherein the guide comprises at least one pair of oppositely facing tabs.

4. The system of claim 1, wherein the guide comprises at least one pair of tabs disposed spaced apart from each other corresponding to a lateral dimension of the printed circuit board assembly.

5. The system of claim 1, further comprising a grounding element adapted to be coupled to the mounting post.

6. The system of claim 1, further comprising a grounding element extending from the printed circuit board assembly to the chassis support.

7. The system of claim 1, wherein the guide is adapted to restrict lateral movement of the printed circuit board assembly.

8. A printed circuit board assembly mounting system, comprising:
a mounting post coupled to a printed circuit board assembly; and
a computer chassis having at least one support member, the support member having a keyhole adapted to receive the mounting post, the support member further having at least one guide adapted to align the mounting post with the keyhole, the mounting post adapted to slidably engage the keyhole to secure the printed circuit board assembly to the support member.

9. The system of claim 8, wherein the guide comprises integrally formed tabs of the support member.

10. The system of claim 8, wherein the guide comprises at least one pair of oppositely facing tabs.

11. The system of claim 8, further comprising at least one grounding element adapted to be coupled to the mounting post.

12. The system of claim 8, further comprising at least one grounding element extending from the printed circuit board assembly to the support member.

13. The system of claim 8, wherein the guide comprises at least one pair of tabs disposed spaced apart from each other corresponding to a lateral dimension of the printed circuit board assembly.

14. The system of claim 8, wherein the guide is adapted to restrict lateral movement of the printed circuit board assembly.

15. A printed circuit board assembly mounting system, comprising:
a printed circuit board assembly;
a chassis support member;
means for releasably coupling the printed circuit board assembly to the chassis support member;
means formed in the chassis support member for enabling slidable engagement of the coupling means with the chassis support member; and
means for aligning the coupling means with the means for enabling slidable engagement.

16. The system of claim 15, wherein the means for aligning comprises means for restricting lateral movement of the printed circuit board assembly.

17. The system of claim 15, further comprising grounding means coupled to the coupling means.

18. The system of claim 15, wherein the means for aligning comprises a plurality of tabs having a lateral spacing corresponding to a lateral dimension of the printed circuit board assembly.

19. The system of claim 15, wherein the means for aligning comprises at least one pair of tabs.
